(19) United States
(12) Patent Application Publication
(10) Pub. No.: US 2026/0164958 A1
(43) Pub. Date: Jun. 11, 2026

(54) DISPLAY DEVICES AND METHODS OF MANUFACTURING DISPLAY DEVICES

(71) Applicant: Sharp Display Technology Corporation, Kameyama City, Mie (JP)

(72) Inventors: Tetsunori TANAKA, Kameyama City, Mie (JP); Seiji KANEKO, Kameyama City, Mie (JP); Tetsuo FUJITA, Kameyama City, Mie (JP)

(21) Appl. No.: 18/708,009

(22) PCT Filed: Dec. 29, 2021
(86) PCT No.: PCT/JP2021/049017

§ 371 Date: May 7, 2024

(51) Int. Cl. H10K 59/131; H10K 59/12; H10K 59/40; H10K 102/00

(52) U.S. Cl. CPC H10K 59/131; H10K 59/1201; H10K 59/40; H10K 2102/311

(57) ABSTRACT

A display device includes: a base substrate; a thin film transistor layer; a light-emitting element layer constituting at least a part of a display area; a sealing film; and a touch panel layer constituting at least a part of a touch panel, the display device further comprising: a frame area; a terminal section in the frame area; and a bending portion between the terminal section and the display area, wherein in the sealing film in the frame area, a bending portion side end portion is provided between the bending portion and the display area, on the sealing film, a plurality of lead wires drawn out from the touch panel are provided, the plurality of lead wires constituting at least a part of the touch panel layer, and the plurality of lead wires do not straddle the bending portion side end portion of the sealing film.

### TECHNICAL FIELD

The disclosure relates to display devices and methods of manufacturing display devices.

### BACKGROUND ART

The organic EL display device, or the self-luminous display device built around organic electroluminescence elements (hereinafter, may be referred to as “organic EL elements”), has been attracting attention as a promising successor to the liquid crystal display device. Display devices have been proposed that incorporate a built-in touch panel in such an organic EL display device.

For instance, Patent Literature 1 discloses an organic EL display device including; a display area; and a terminal section provided in a peripheral region around the display area, wherein the display area is covered by touch sensors that are a part of the touch panel. This organic EL display device further includes, on an organic EL layer in the display area, a sealing film that is a stack of an inorganic film and an organic film, and the touch sensors are provided on this sealing film. Then, lead wires from the touch sensors are extended to the terminal section and connected to a touch-sensor-use flexible wiring board for driving the touch sensors, to enable reception and transmission of touch-sensor-use signals.

### CITATION LIST

### Patent Literature

Patent Literature 1: Japanese Unexamined Patent Application Publication No. 2018-112690

### SUMMARY

### Technical Problem

In the organic EL display device of Patent Literature 1, for example, as shown in FIG. 17, the lead wires from the touch sensors are arranged to straddle (traverse) the ends of a first protective film and a third protective film each made of, for example, a film of an inorganic material such as SiN that are parts of the sealing film.

In addition, in the organic EL display device in which the touch panel is provided on the sealing film as described above, in other words, in the organic EL display device including an on-cell touch panel which has an on-cell structure (hereinafter, may be referred to as “OCT”), attempts have been made to reduce the area occupied by the frame area in a plan view, hence to narrow down the frame, by, for example, bending the peripheral region (frame area). In such an organic EL display device, the inorganic film in the sealing film (hereinafter, may be referred to as the “TFE (thin film encapsulation) film”) is removed from the vicinity of the bending portion to allow for the 180° bending structure in the frame area. Therefore, those wires drawn out from the touch panel (hereinafter, may be referred to as “lead wires”) are structured in such a manner as to straddle the ends of the removed TFE film at positions closer to the display area than to the bending portion.

Here, the TFE film is made of, for example, an inorganic film stack including a plurality of inorganic films that are sequentially formed by plasma CVD (chemical vapor deposition) (hereinafter, may be referred to as “TFE-CVD films”). When the TFE-CVD films are patterned not by photolithography, but using a CVD mask, the film quality will likely be unstable at the ends of openings in the mask (ends of the TFE-CVD films). In particular, when the TFE-CVD film that is formed first (the underlying TFE-CVD film; hereinafter, may be referred to as the “first CVD film”) is made of a material containing silicon oxynitride (SiON) as a primary component, the SiON-based, first CVD film will likely to change its nature in a high-temperature, high-humidity environment. This change of the nature could lead to an increase in volume, hence in load (tensile stress), possibly causing cracks in films overlying the first CVD film (e.g., a protective layer on the lead wires), and the lead wires may consequently be corroded.

As described above, in the known OCT-mounted organic EL display device in which the lead wires are arranged to straddle the ends of the TFE-CVD films, the touch panel can develop defects.

The disclosure, made in view of these issues, has an object of restraining corrosion of lead wires drawn out from a touch panel in organic EL display devices that include an OCT and a bending structure.

### Solution to Problem

To achieve the object, a display device in accordance with the disclosure includes: a base substrate; a thin film transistor layer on the base substrate; a light-emitting element layer on the thin film transistor layer, the light-emitting element layer constituting at least a part of a display area; a sealing film provided so as to cover the light-emitting element layer; and a touch panel layer on the sealing film, the touch panel layer constituting at least a part of a touch panel, and further includes: a frame area around the display area; a terminal section in the frame area; and a bending portion between the terminal section and the display area, the bending portion being configured so as to extend in a single direction, wherein in the sealing film in the frame area, a bending portion side end portion is provided between the bending portion and the display area, on the sealing film, a plurality of lead wires drawn out from the touch panel are provided, the plurality of lead wires constituting at least a part of the touch panel layer, and the plurality of lead wires do not straddle the bending portion side end portion of the sealing film.

A method of manufacturing a display device in accordance with the disclosure is a method of manufacturing a display device including: a base substrate; a thin film transistor layer on the base substrate; a light-emitting element layer on the thin film transistor layer, the light-emitting element layer constituting at least a part of a display area; a sealing film provided so as to cover the light-emitting element layer; and a touch panel layer on the sealing film, the touch panel layer constituting at least a part of a touch panel, and further including: a frame area around the display area; a terminal section in the frame area; and a bending portion between the terminal section and the display area, the bending portion being configured so as to extend in a single direction, the method including: a thin film transistor layer formation step of forming the thin film transistor layer on the base substrate; a light-emitting element layer formation step of forming the light-emitting element layer on the thin film transistor layer; a sealing film formation step of forming the sealing film so as to cover the light-emitting element layer; and a touch panel layer formation step of forming the touch panel layer on the sealing film, wherein the touch panel layer formation step includes a lead wire formation step of forming a plurality of lead wires on the sealing film, the plurality of lead wires being drawn out from the touch panel and constituting at least a part of the touch panel layer, and when in the sealing film formation step, the sealing film in the frame area is patterned to form a bending portion side end portion between the bending portion and the display area, a film-forming region of the sealing film is expanded toward the bending portion side so that the plurality of lead wires do not straddle the bending portion side end portion of the sealing film.

### Advantageous Effects of Disclosure

The disclosure enables restraining corrosion of lead wires drawn out from a touch panel in organic EL display devices that include an OCT and a bending structure.

### BRIEF DESCRIPTION OF DRAWINGS

FIG. 1 is a schematic plan view of a structure of an organic EL display device in accordance with a first embodiment of the disclosure.

FIG. 2 is a plan view of a display area of the organic EL display device in accordance with the first embodiment of the disclosure.

FIG. 3 is a cross-sectional view of the display area of the organic EL display device in accordance with the first embodiment of the disclosure.

FIG. 4 is an equivalent circuit diagram of a TFT layer in the organic EL display device in accordance with the first embodiment of the disclosure.

FIG. 5 is a cross-sectional view of an organic EL layer in the organic EL display device in accordance with the first embodiment of the disclosure.

FIG. 6 is a schematic plan view of a structure of a touch panel in the organic EL display device in accordance with the first embodiment of the disclosure.

FIG. 7 is a cross-sectional view of a frame area shown in FIG. 6, taken along line VII-VII FIG. 8 is an enlarged cross-sectional view of the frame area in a bending portion side shown in FIG. 7.

FIG. 9 is a cross-sectional view of a frame area in the bending portion side of an organic EL display device in accordance with a second embodiment of the disclosure and corresponds to FIG. 7.

FIG. 10 is an enlarged cross-sectional view of a frame area in the bending portion side of an organic EL display device in accordance with a third embodiment of the disclosure and corresponds to FIG. 8.

### DESCRIPTION OF EMBODIMENTS

The following will describe embodiments of the disclosure in detail with reference to drawings. Note that the disclosure is not limited to the embodiments below.

### First Embodiment

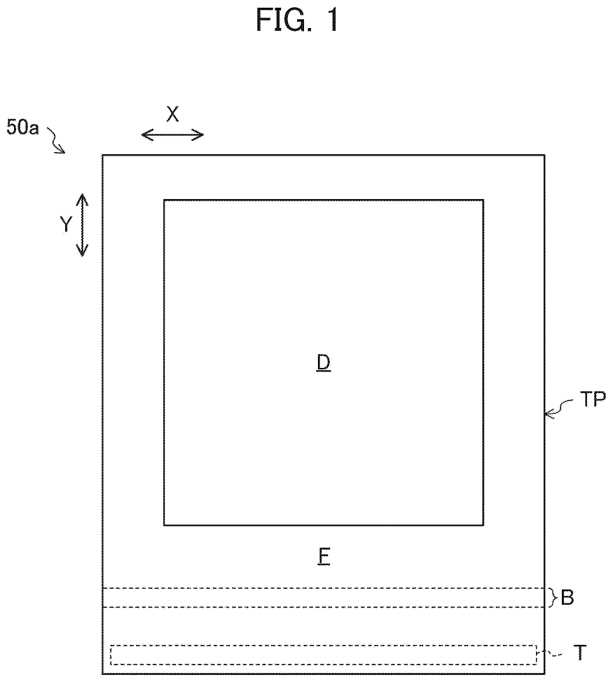

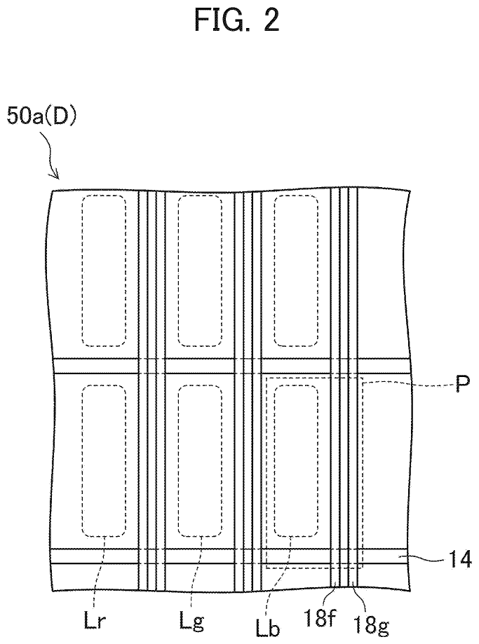

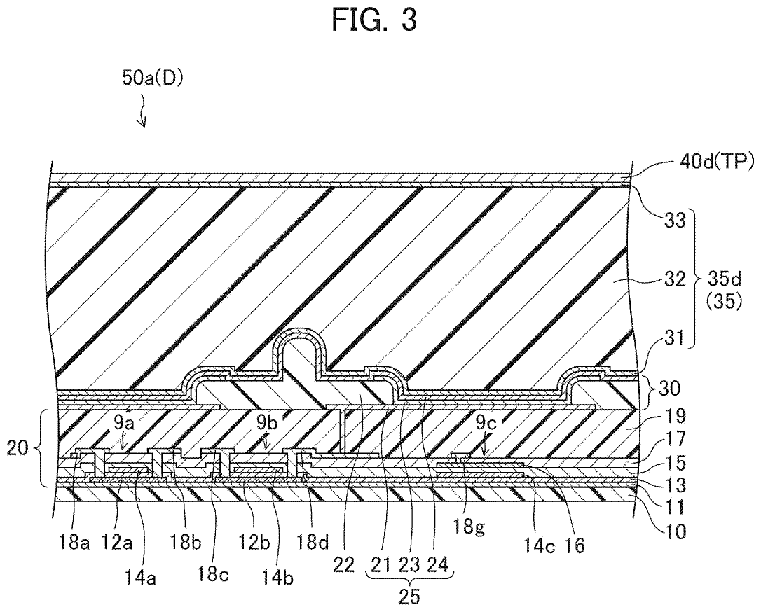

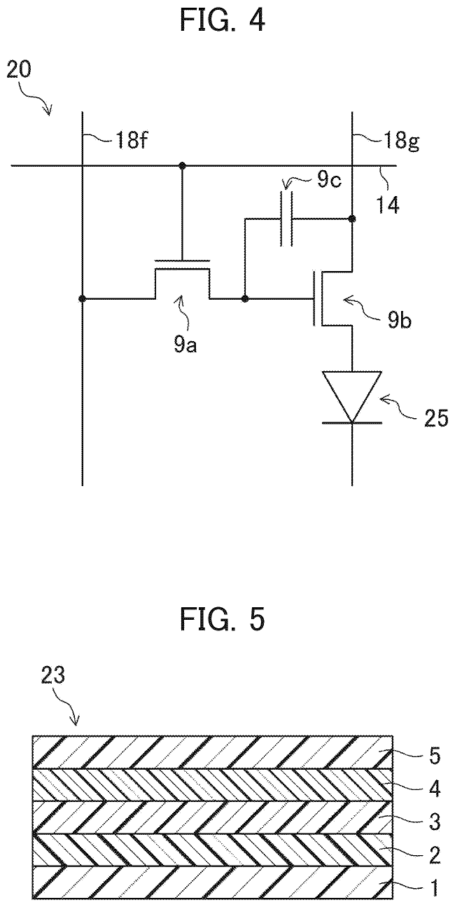

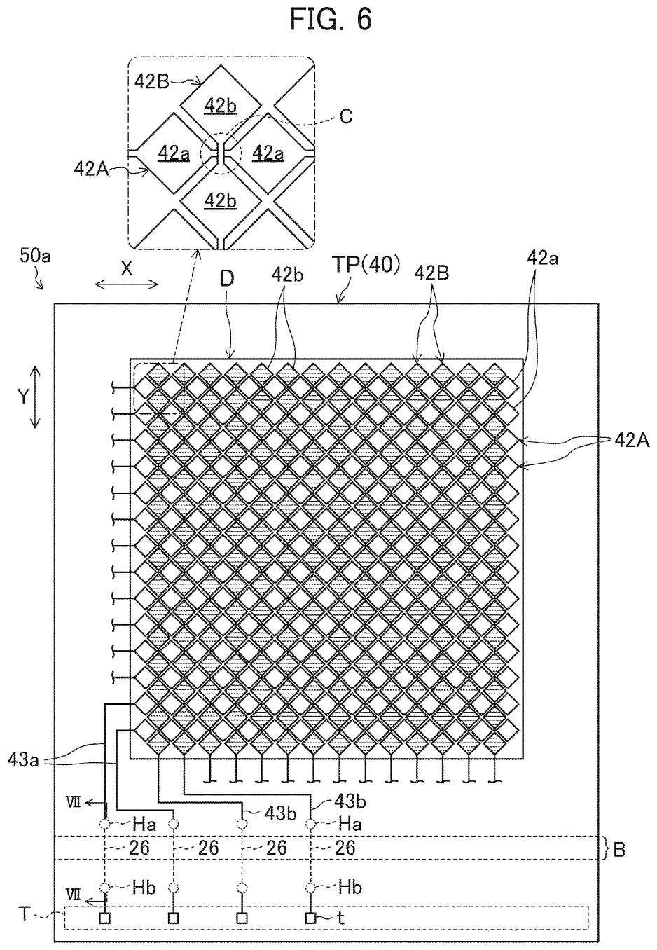

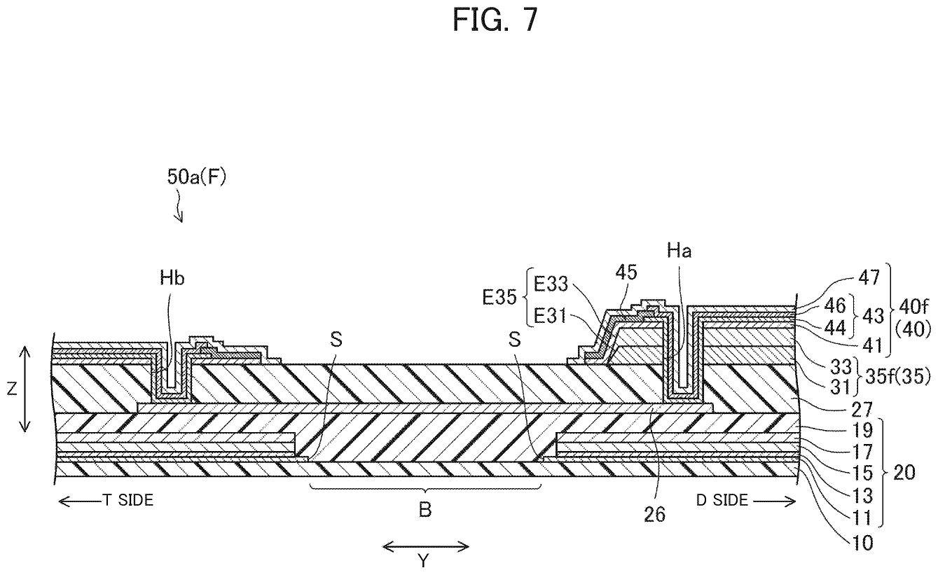

FIGS. 1 to 8 represent a first embodiment of a display device in accordance with the disclosure. Note that each embodiment below will discuss an organic EL display device including organic EL elements as an example of a display device including light-emitting elements. Here, FIG. 1 is a schematic plan view of a structure of an organic EL display device 50a in accordance with the present embodiment. FIGS. 2 and 3 are a plan view and a cross-sectional view, respectively, of a display area D of the organic EL display device 50a. FIG. 4 is an equivalent circuit diagram of a TFT layer 20 in the organic EL display device 50a. FIG. 5 is a cross-sectional view of an organic EL layer 23 in the organic EL display device 50a. FIG. 6 is a schematic plan view of a structure of a touch panel TP in the organic EL display device 50a. FIG. 7 is a cross-sectional view of a frame area F shown in FIG. 6, taken along line VII-VII. FIG. 8 is an enlarged cross-sectional view of the frame area F toward the bending portion B shown in FIG. 7.

The organic EL display device 50a includes, for example: the rectangular display area D (display panel) for producing an image display; and the frame area F provided like a frame around the display area D, as shown in FIG. 1. Note that this rectangular shape of the display area D encompasses, for example, generally rectangular shapes such as those with a curved side(s), those with a round corner(s), and those with a notched side(s). Note that in the organic EL display device 50a, directions X, Y, and Z are defined where direction X is parallel to the surface of a resin substrate 10 (detailed later) (see FIGS. 1 and 6), direction Y is perpendicular to direction X and parallel to the surface of the resin substrate 10 (see FIG. 1 and FIGS. 6 to 8), and direction Z is perpendicular to both direction X and direction Y (see FIGS. 7 and 8).

There is provided a matrix of subpixels P in the display area D as shown in FIG. 2. In addition, in the display area D, for example, a subpixel P including a red-light-emission region Lr for producing a red display, a subpixel P including a green-light-emission region Lg for producing a green display, and a subpixel P including a blue-light-emission region Lb for producing a blue display are provided adjacent to each other as shown in FIG. 2. Note that each pixel in the display area D is formed by, for example, three adjacent subpixels P respectively including a red-light-emission region Lr, a green-light-emission region Lg, and a blue-light-emission region Lb.

Toward the lower end of the frame area F in FIG. 1 is there provided a terminal section T for connecting to external circuitry. The terminal section T includes, for example, a plurality of terminals t for feeding signals to the display panel (see FIG. 6) and a plurality of terminals t for applying voltages across the touch panel TP (detailed later), all arranged along direction X.

In addition, the frame area F includes a bending portion B extending in direction X between the display area D and the terminal section T as shown in FIG. 1. The bending portion B can be bent 180° around the horizontal direction (direction X) in the drawing (to form a U-shape).

Referring to FIG. 3, the organic EL display device 50a includes: the resin substrate 10 as a base substrate; the thin film transistor (hereinafter, may be referred to as “TFT”) layer 20 on the resin substrate 10; an organic EL element layer 30 as a light-emitting element layer that is a part of the display area D on the TFT layer 20; a sealing film 35 on the organic EL element layer 30 (hereinafter, the sealing film 35 on the display area D may be referred to as the “sealing film 35d”); and a touch panel layer 40 that is a part of the touch panel TP on the sealing film 35d (hereinafter, the touch panel layer 40 on the display area D may be referred to as the “touch panel layer 40d”). The organic EL display device 50a is an organic EL display device including an on-cell touch panel (OCT) which allows the user to make inputs by touching the display screen.

The resin substrate 10 is made of, for example, a polyimide resin.

Referring to FIG. 3, the TFT layer 20 includes: a base coat film 11 (hereinafter, may be referred to as a “first the base coat film 11”) on the resin substrate 10; a plurality of first TFTs 9a, a plurality of second TFTs 9b, and a plurality of capacitors 9c, all on the first the base coat film 11; and a planarization film 19 on the first TFTs 9a, the second TFTs 9b, and the capacitors 9c. Here, referring to FIG. 3, the TFT layer 20 includes: the first the base coat film 11; semiconductor layers 12a and 12b; a gate insulating film 13; a first wiring layer including, for example, gate lines 14 (see FIG. 2), gate electrodes 14a, 14b, and a lower conductive layer 14c; a first interlayer insulating film 15; a second wiring layer including, for example, an upper conductive layer 16; a second interlayer insulating film 17; a third wiring layer including, for example, source lines 18f (see FIG. 2), source electrodes 18a, 18c, drain electrodes 18b, 18d, and power supply lines 18g; and the planarization film 19, all of which are stacked sequentially on the resin substrate 10. In addition, referring to FIGS. 2 and 4, the TFT layer 20 includes the plurality of gate lines 14 extending parallel to each other in the horizontal direction in the drawing. In addition, referring to FIGS. 2 and 4, the TFT layer 20 includes the plurality of source lines 18f extending parallel to each other in the vertical direction in the drawing. In addition, referring to FIGS. 2 and 4, the TFT layer 20 includes the plurality of power supply lines 18g extending parallel to each other in the vertical direction in the drawing. Note that the power supply lines 18g are provided adjacent to the source lines 18f as shown in FIG. 2. In addition, in the TFT layer 20, referring to FIG. 4, each subpixel P includes a first TFT 9a, a second TFT 9b, and a capacitor 9c.

The first the base coat film 11, the gate insulating film 13, the first interlayer insulating film 15, and the second interlayer insulating film 17 each include, for example, either a monolayer film of, for example, an inorganic insulating film such as silicon nitride (SiNx (x is a positive integer)), silicon oxide (SiO₂), or silicon oxynitride (SiON) or a stack of any of these films. The semiconductor layers 12a and 12b each include, for example, a low-temperature polysilicon film or an In—Ga—Zn—O-based oxide semiconductor film. The first wiring layer, the second wiring layer, and the third wiring layer each include, for example, either a metal monolayer film of, for example, molybdenum (Mo), titanium (Ti), aluminum (Al), copper (Cu), or tungsten (W) or a stacked metal layer film of, for example, Mo (top layer)/Al (middle layer)/Mo (bottom layer), Ti/Al/Ti, Al (top layer)/Ti (bottom layer), Cu/Mo, or Cu/Ti. Note that the third wiring layer preferably includes a stacked metal layer film of, for example, Ti/Al/Ti.

The first TFTs 9a and the second TFTs 9b are p-type TFTs with the semiconductor layers 12a and 12b (detailed later) being doped with, for example, an impurity such as boron.

Referring to FIG. 4, in each subpixel P, the first TFT 9a is electrically connected to an associated one of the gate lines 14 and an associated one of the source lines 18f. In addition, referring to FIG. 3, the first TFT 9a includes the semiconductor layer 12a, the gate insulating film 13, the gate electrode 14a, the first interlayer insulating film 15, the second interlayer insulating film 17, the source electrode 18a, and the drain electrode 18b, all of which are provided sequentially on the first the base coat film 11. Here, referring to FIG. 3, the semiconductor layer 12a is provided in an insular manner on the first the base coat film 11 and includes, for example, a channel region, a source region, and a drain region. In addition, referring to FIG. 3, the gate insulating film 13 is provided so as to cover the semiconductor layer 12a. In addition, referring to FIG. 3, the gate electrode 14a is provided on the gate insulating film 13 so as to overlap the channel region in the semiconductor layer 12a. In addition, referring to FIG. 3, the first interlayer insulating film 15 and the second interlayer insulating film 17 are sequentially provided so as to cover the gate electrodes 14a. In addition, referring to FIG. 3, the source electrode 18a and the drain electrode 18b are provided on the second interlayer insulating film 17 at a distance from each other. In addition, referring to FIG. 3, the source electrode 18a and the drain electrode 18b are electrically connected respectively to the source region and the drain region in the semiconductor layer 12a via contact holes formed in the stack of the gate insulating film 13, the first interlayer insulating film 15, and the second interlayer insulating film 17.

Referring to FIG. 4, the second TFTs 9b is electrically connected to an associated one of the first TFTs 9 a and an associated one of the power supply lines 18g in each subpixel P. In addition, referring to FIG. 3, the second TFT 9b includes the semiconductor layer 12b, the gate insulating film 13, the gate electrode 14b, the first interlayer insulating film 15, the second interlayer insulating film 17, the source electrode 18c, and the drain electrode 18d, all of which are sequentially provided on the first the base coat film 11. Here, referring to FIG. 3, the semiconductor layer 12b is provided in an insular manner on the first the base coat film 11 and has, for example, a channel region, a source region, and a drain region. In addition, referring to FIG. 3, the gate insulating film 13 is provided so as to cover the semiconductor layer 12b. In addition, referring to FIG. 3, the gate electrode 14b is provided on the gate insulating film 13 so as to overlap the channel region in the semiconductor layer 12b. In addition, referring to FIG. 3, the first interlayer insulating film 15 and the second interlayer insulating film 17 are sequentially provided so as to cover the gate electrodes 14b. In addition, referring to FIG. 3, the source electrode 18c and the drain electrode 18d are provided on the second interlayer insulating film 17 at a distance from each other. In addition, referring to FIG. 3, the source electrode 18c and the drain electrode 18d are electrically connected respectively to the source region and the drain region in the semiconductor layer 12b via contact holes formed in the stack of the gate insulating film 13, the first interlayer insulating film 15, and the second interlayer insulating film 17.

Note that although the present embodiment discusses the first TFTs 9a and the second TFTs 9b both of which have a top gate structure as an example, the first TFTs 9a and the second TFTs 9b may alternatively be bottom-gate TFTs.

Referring to FIG. 4, the capacitor 9c is electrically connected to an associated one of the first TFTs 9 a and an associated one of the power supply lines 18g in each subpixel P. Here, referring to FIG. 3, the capacitor 9c includes: the lower conductive layer 14c; the first interlayer insulating film 15 provided so as to cover the lower conductive layer 14c; and the upper conductive layer 16 provided on the first interlayer insulating film 15 so as to overlap the lower conductive layer 14c. Note that referring to FIG. 3, the upper conductive layer 16 is electrically connected to the power supply line 18g via a contact hole formed in the second interlayer insulating film 17.

The planarization film 19 (hereinafter, may be referred to as the “first the planarization film 19”) has a flat surface in the display area D and is made of, for example, an organic resin material, such as a polyimide resin or an acrylic resin or a polysiloxane-based SOG (spin on glass) material.

Referring to FIG. 3, the organic EL element layer 30 includes a plurality of organic EL elements 25 as a plurality of light-emitting elements arranged in a matrix correspondingly to the plurality of subpixels P.

Referring to FIG. 3, the organic EL element 25 includes: a first electrode 21 on the planarization film 19 for each subpixel P; the organic EL layer 23 on the first electrode 21 for each subpixel P; and a second electrode 24 on the organic EL layer 23 commonly to the plurality of subpixels P.

Referring to FIG. 3, the first electrode 21 is electrically connected the drain electrode 18d of the second TFT 9b in each subpixel P via a contact hole formed in the planarization film 19. In addition, the first electrode 21 has a function of injecting holes to the organic EL layer 23. In addition, the first electrode 21 is more preferably made of a material having a large work function to improve the efficiency of hole injection to the organic EL layer 23. Here, the first electrode 21 may be made of, for example, a metal material such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), or tin (Sn). Alternatively, the first electrode 21 may be made of, for example, an alloy such as an astatine-astatine oxide (At—AtO₂) alloy. As a further alternative, the first electrode 21 may be made of, for example, an electrically conductive oxide such as tin oxide (SnO), zinc oxide (ZnO), indium tin oxide (ITO), or indium zinc oxide (IZO). As another alternative, the first electrode 21 may include a stack of layers of any two or more of these materials. Note that examples of compound materials with a large work function include indium tin oxide (ITO) and indium zinc oxide (IZO). Furthermore, the first electrode 21 has its peripheral end portion covered by an edge cover 22 provided commonly to the plurality of subpixels P and shaped like a lattice. Here, the edge cover 22 is made of, for example, a positive-type photosensitive resin material such as a polyimide resin, an acrylic resin, a polysiloxane resin, or a novolac resin or a polysiloxane-based SOG material.

Referring to FIG. 5, the organic EL layer 23 includes a hole injection layer 1, a hole transport layer 2, a light-emitting layer 3, an electron transport layer 4, and an electron injection layer 5, all of which are sequentially provided on the first electrodes 21.

The hole injection layer 1 is alternatively referred to as an anode buffer layer and has a function of improving the efficiency of hole injection from the first electrode 21 to the organic EL layer 23 by bringing the energy levels of the first electrode 21 and the organic EL layer 23 closer to each other. Here, the hole injection layer 1 is made of, for example, a triazole derivative, an oxadiazole derivative, an imidazole derivative, a polyaryl alkane derivative, a pyrazoline derivative, a phenylenediamine derivative, an oxazole derivative, a styryl anthracene derivative, a fluorenone derivative, a hydrazone derivative, or a stilbene derivative.

The hole transport layer 2 has a function of improving the efficiency of hole transport from the first electrode 21 to the organic EL layer 23. Here, the hole transport layer 2 is made of, for example, a porphyrin derivative, an aromatic tertiary amine compound, a styryl amine derivative, a polyvinyl carbazole, poly-p-phenylene vinylene, polysilane, a triazole derivative, an oxadiazole derivative, an imidazole derivative, a polyaryl alkane derivative, a pyrazoline derivative, a pyrazolone derivative, a phenylenediamine derivative, an aryl amine derivative, an amine-substituted chalcone derivative, an oxazole derivative, a styryl anthracene derivative, a fluorenone derivative, a hydrazone derivative, a stilbene derivative, hydrogenated amorphous silicon, hydrogenated amorphous silicon carbide, zinc sulfide, and zinc selenide.

The light-emitting layer 3 is a region into which the first electrode 21 and the second electrode 24 inject holes and electrons respectively for recombination when voltage is applied by the first electrode 21 and the second electrode 24. Here, the light-emitting layer 3 is made of a material with a high luminous efficiency. Then, the light-emitting layer 3 is made of, for example, a metal oxinoid compound [8-hydroxy quinoline metal complex], a naphthalene derivative, an anthracene derivative, a diphenyl ethylene derivative, a vinyl acetone derivative, a triphenyl amine derivative, a butadiene derivative, a coumarin derivative, a benzoxazole derivative, an oxadiazole derivative, an oxazole derivative, a benzimidazole derivative, a thiadiazole derivative, a benzthiazole derivative, a styryl derivative, a styryl amine derivative, a bis(styryl)benzene derivative, a tris(styryl)benzene derivative, a perylene derivative, a perynone derivative, an amino pyrene derivative, a pyridine derivative, a rhodamine derivative, an acridine derivative, phenoxazone, a quinacridone derivative, rubrene, poly-p-phenylene vinylene, and polysilane.

The electron transport layer 4 has a function of efficiently transporting electrons to the light-emitting layer 3. Here, the electron transport layer 4 is made of, for example, an organic compound such as an oxadiazole derivative, a triazole derivative, a benzoquinone derivative, a naphthoquinone derivative, an anthraquinone derivative, a tetracyanoanthraquinodimethane derivative, a diphenoquinone derivative, a fluorenone derivative, a silole derivative, or a metal oxinoid compound.

The electron injection layer 5 has a function of improving the efficiency of electron injection from the second electrode 24 to the organic EL layer 23 by bring the energy levels of the second electrode 24 and the organic EL layer 23 closer to each other and reduces the drive voltage of the organic EL element 25 by this function. Note that the electron injection layer 5 is alternatively referred to as the cathode buffer layer. Here, the electron injection layer 5 is made of, for example, an inorganic alkali compound such as lithium fluoride (LiF), magnesium fluoride (MgF₂), calcium fluoride (CaF₂), strontium fluoride (SrF₂), or barium fluoride (BaF₂) aluminum oxide (Al₂O₃), or strontium oxide (SrO).

Referring to FIG. 3, the second electrode 24 is provided so as to cover the organic EL layer 23 and the edge cover 22 of each subpixel P. In addition, the second electrode 24 has a function of injecting electrons to the organic EL layer 23. In addition, the second electrode 24 is more preferably made of a material with a small work function to improve the efficiency of electron injection to the organic EL layer 23. Here, the second electrode 24 is made of, for example, silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), or lithium fluoride (LiF). In addition, the second electrode 24 may be made of, for example, an alloy such as a magnesium-copper (Mg—Cu) alloy, a magnesium-silver (Mg—Ag) alloy, a sodium-potassium (Na—K) alloy, an astatine-astatine oxide (At—AtO₂) alloy, a lithium-aluminum (Li—Al) alloy, a lithium-calcium-aluminum (Li—Ca—Al) alloy, or a lithium fluoride-calcium-aluminum (LiF—Ca—Al) alloy. In addition, the second electrode 24 may be made of, for example, an electrically conductive oxide such as tin oxide (SnO), zinc oxide (ZnO), indium tin oxide (ITO), or indium zinc oxide (IZO). Alternatively, the second electrode 24 may be made of a stack of layers of any of these materials. Note that examples of materials with a small work function include magnesium (Mg), lithium (Li), lithium fluoride (LiF), a magnesium-copper (Mg—Cu) alloy, a magnesium-silver (Mg—Ag) alloy, a sodium-potassium (Na—K) alloy, a lithium-aluminum (Li—Al) alloy, a lithium-calcium-aluminum (Li—Ca—Al) alloy, and a lithium fluoride-calcium-aluminum (LiF—Ca—Al) alloy.

Referring to FIG. 3, the sealing film 35d is provided on the organic EL element layer 30 so as to cover the organic EL elements 25. Here, referring to FIG. 3, the sealing film 35d includes: a first inorganic sealing film 31 provided so as to cover the second electrode 24; an organic sealing film 32 provided on the first inorganic sealing film 31; and a second inorganic sealing film 33 provided so as to cover the organic sealing film 32 and has a function of protecting the organic EL layer 23 from, for example, moisture and oxygen. Here, the first inorganic sealing film 31 and the second inorganic sealing film 33 are made of, for example, silicon oxide (SiO₂), aluminum oxide (Al₂O₃), silicon nitride (SiNx where x is a positive number) such as trisilicon tetranitride (Si₃N₄) or silicon oxynitride (SiON), or an inorganic material such as silicon carbide nitride (SiCN). In addition, the organic sealing film 32 is made of, for example, an organic material such as an acrylic resin, a polyurea resin, a parylene resin, a polyimide resin, or a polyamide resin.

Referring to FIG. 3, the touch panel layer 40d (touch panel TP) is provided on the sealing film 35d providing the top face of the display area D (specifically, on the second inorganic sealing film 33 providing the top face of the sealing film 35d) for the purpose of reducing the thickness. In other words, the display area D is covered by the touch panel TP. Hence, a display panel capable of detecting the location touched by a touch body such as the user's finger or stylus in the display area D.

Referring to FIG. 6, the touch panel TP includes, in the display area D, first touch electrodes 42a and second touch electrodes 42b (hereinafter, may be collectively referred to as “touch electrodes 42”) and first lead wires 43a and second lead wires 43b (hereinafter, may be collectively referred to as “lead wires 43”).

There are provided a plurality of touch electrodes 42 as touch sensors for detecting a touch position (transferring results of measurement on the touch panel TP). The plurality of first touch electrodes 42a and the plurality of second touch electrodes 42b are arranged in matrices respectively (specifically, obliquely and alternately aligned in with respect to direction X and direction Y).

The first touch electrode 42a is shaped like, for example, a rhombus. The first touch electrodes 42a adjacent in direction X and direction Y have corners facing each other. Then, the corners of the first touch electrodes 42a adjacent in direction X are coupled to each other. The plurality of first touch electrodes 42a aligned in direction X provide first touch electrode groups 42A electrically connected to each other. There are provided a plurality of rows of first touch electrode groups 42A along direction Y.

The second touch electrode 42b is also shaped like, for example, a rhombus. The second touch electrodes 42b adjacent in direction X and direction Y have corners facing each other. Then, the corners of the second touch electrodes 42b adjacent in direction Y are coupled to each other. The plurality of second touch electrodes 42b aligned in direction Y provide second touch electrode groups 42B electrically connected to each other. There are provided a plurality of columns of second touch electrode groups 42B along direction X.

There are provided a plurality of lead wires 43 as wiring drawn out from the plurality of touch electrodes 42 to provide the touch sensors for the touch panel TP. The plurality of lead wires 43 are drawn out from the periphery of the display area D (the left and bottom sides of the display area D in FIG. 6) to the frame area F and further toward the bending portion B (direction Y) and terminated immediately before reaching the bending portion B.

The first lead wire 43a (the display area D side end thereof) is electrically connected to the first touch electrode 42a located at an end (left end in FIG. 6) of the first touch electrode group 42A for each first touch electrode group 42A. Meanwhile, the bending portion B side end of the first lead wire 43a is drawn out through a portion that forms one of sides of the frame area F (left side in FIG. 6) in direction X toward the bending portion B and terminated immediately before reaching the bending portion B. Note that the first lead wire 43a may pass through a portion that forms the other side of the frame area F (right side in FIG. 6) in direction X.

The second lead wires 43b (the display area D side end thereof) is electrically connected to the second touch electrode 42b located at an end (bottom end in FIG. 6) of the second touch electrode group 42B for each second touch electrode group 42B. Meanwhile, the bending portion B side end of the second lead wire 43b is drawn out through a portion that forms a side of the frame area F facing the bending portion B (bottom end in FIG. 6) toward the bending portion B and terminated immediately before reaching the bending portion B.

Note that the first lead wires 43a and the second lead wires 43b, drawn out toward the bending portion B, are connected respectively to the terminals t of the terminal section T via bend lines 26 (detailed later).

The touch panel TP may have a mutual-capacitance type of wiring structure. The first touch electrode group 42A, formed by the plurality of first touch electrodes 42a, functions as, for example, a detection electrode (sense electrode, receiver). Meanwhile, the second touch electrode group 42B, formed by the plurality of second touch electrodes 42b, functions as, for example, a drive electrode (transmitter). Note that the first touch electrode group 42A and the second touch electrode group 42B are not necessarily limited in function as above and may swap their functions. In addition, the touch panel TP does not necessarily have the wiring structure described here and may have, for example, a self-capacitance type or a (projected capacitive) type of wiring structure.

The touch electrodes 42 and the lead wires 43 are made of a first conductive layer and/or a second conductive layer respectively. For example, the first touch electrodes 42a are made of the same material, and provided in the same layer, as the second conductive layer. The second touch electrodes 42b are structured so that the first conductive layer can intersect with the second conductive layer. Specifically, second connecting lines coupling the second touch electrodes 42b together in direction Y intersect at intersections C shown in FIG. 6 with first connecting lines coupling the first touch electrodes 42a together in direction X. Therefore, either the first touch electrodes 42a (first connecting lines) or the second touch electrodes 42b (second connecting lines) are formed by the first conductive layer, and the rest is formed by the second conductive layer, at the intersections C. The lead wires 43 are formed by a stack of films in which the first conductive layer and the second conductive layer are sequentially stacked. Note that the first conductive layer and the second conductive layer are made of, for example: a metal monolayer film of, for example, molybdenum (Mo), titanium (Ti), aluminum (Al), copper (Cu), or tungsten (W); a stack of metal films of, for example, Mo (top layer)/Al (middle layer)/Mo (bottom layer), Ti/Al/Ti, Al (top layer)/Ti (bottom layer), Cu/Mo, or Cu/Ti; or an electrically conductive oxide such as indium tin oxide (ITO) or indium zinc oxide (IZO). The first conductive layer and the second conductive layer may be made of the same material or different materials.

The touch electrodes 42 may include a mesh of wiring, common wiring (common layer), or wiring in the form of electrode pads. The touch electrodes 42, when they are wiring having, for example, a Ti/Al/Ti layered structure, are preferably formed like a mesh because they are non-transparent electrodes (they may block light). On the other hand, the touch electrodes 42, when they are wiring made of, for example, ITO, may be formed like a mesh or as common wiring because they are transparent electrodes.

In addition, referring to FIGS. 6 and 7, the organic EL display device 50a includes, in the frame area F toward the bending portion B: the resin substrate 10; the TFT layer 20 provided on the resin substrate 10; the plurality of bend lines 26 provided on the TFT layer 20; a planarization film 27 provided so as to cover the plurality of bend lines 26 (hereinafter, may be referred to as a “second planarization film 27”); the sealing film 35 provided on the second planarization film 27 (hereinafter, the sealing film 35 provided on the frame area F may be referred to as the “sealing film 35f”); and the touch panel layer 40 provided on the second planarization film 27 or the sealing film 35f (hereinafter, the touch panel layer 40 provided on the frame area F may be referred to as the touch panel layer 40f). The organic EL display device 50a includes an OCT mounted thereto, and as shown in FIGS. 6 and 7, has a bending structure where the organic EL display device 50a can be bent around the bending portion B.

Referring to FIG. 7, the organic EL display device 50a has the inorganic film forming the TFT layer 20 and the inorganic film forming the sealing film 35f removed in a region overlapping the bending portion B in a plan view, to accommodate the bending structure.

Referring to FIG. 7, the TFT layer 20 does not include an inorganic film stack in which the first the base coat film 11, the gate insulating film 13, the first interlayer insulating film 15, and the second interlayer insulating film 17 are sequentially stacked, in the region overlapping the bending portion B in a plan view. Specifically, a slit S that runs through the inorganic film stack forming the TFT layer 20 to expose the resin substrate 10 is formed in the TFT layer 20 in the bending portion B. The slit S is formed like a groove that extends all the way through along direction X in which the bending portion B is extended. The slit S is filled with the first the planarization film 19. In other words, the first the planarization film 19 is provided on the resin substrate 10 in the bending portion B.

Referring to FIG. 7, the organic EL display device 50a includes no touch panel layer 40f as a layer overlying the sealing film 35f because no sealing film 35f is present in the bending portion B. Hence, the lead wires 43 forming the touch panel layer 40f are cut immediately before reaching the bending portion B. Therefore, referring to FIGS. 6 and 7, in the bending portion B (and a peripheral region thereof), the bend lines 26 are provided as wiring for connecting the cut lead wires 43 (bending portion B side end portions thereof) to the terminal section T (the terminals t thereof).

As described above, there are provided a plurality of bend lines 26 as wiring for connecting to the plurality of lead wires 43 respectively. Referring to FIG. 6, the bend lines 26 are provided so as to extend in direction Y, which is perpendicular to direction X in which the bending portion B is extended. Referring to FIG. 7, the bend lines 26 are provided on the first the planarization film 19 that provides the top face of the TFT layer 20 in the frame area F toward the bending portion B. Referring to FIGS. 6 and 7, the display area D side ends of the bend lines 26 are electrically connected to the lead wires 43 (specifically, lower lead wires 44) via first contact holes Ha (detailed later). Meanwhile, the terminal section T side ends of the bend lines 26 are electrically connected to the terminal section T (specifically, the terminals t of the terminal section T) via second contact holes Hb (detailed later).

In the organic EL display device 50a including an OCT mounted thereto and also including the bending structure, the lead wires 43, drawn out from the touch electrodes 42 that form the touch panel TP, are electrically connected to the terminals t of the terminal section T via the bend lines 26, the first contact holes Ha, and the second contact holes Hb. Hence, the reception and transmission of touch positions (signals) detected by the touch electrodes 42 is possible. Note that the bend lines 26 are made of the same material, and provided in the same layer, as the third wiring layer (e.g., the source electrodes 18a, 18c, the drain electrodes 18b, 18d, and the power supply lines 18g; see FIG. 3) or an overlying fourth wiring layer (e.g., a conductive layer between the third wiring layer and the first electrodes 21).

Referring to FIG. 7, the second planarization film 27 is provided on the plurality of bend lines 26 and the first the planarization film 19 so as to cover the plurality of bend lines 26. The second planarization film 27 has a flat surface in the frame area F toward the bending portion B and is made of the same material as, for example, the first the planarization film 19.

Referring to FIG. 7, the sealing film 35f is provided on the second planarization film 27. The sealing film 35f is provided along the periphery of the display area D. Referring to FIG. 7, the sealing film 35f is provided in the frame area F toward the bending portion B, extending to immediately before the bending portion B (in the bending portion B close to the display area D). In contrast, no sealing film 35f is provided in the region overlapping the bending portion B in a plan view (in FIG. 7, in the frame area F toward the bending portion B including the bending portion B) to accommodate the bending structure. In other words, an end E35 in the bending portion B side of the sealing film 35f (bending portion B side end portion E35) is formed immediately before the bending portion B. In addition, the sealing film 35f is formed in an inorganic film stack made of the same material, and provided in the same layer, as the first inorganic sealing film 31 and the second inorganic sealing film 33 that form the sealing film 35d. Specifically, the sealing film 35f is an inorganic film (TFE film) that forms a sealing film in the frame area F and is made of an inorganic film stack in which a plurality of inorganic films are sequentially formed by, for example, plasma CVD (TFE-CVD films). Therefore, the bending portion B side end portion E35 of the sealing film 35f (specifically, an end E31 in the bending portion B side of the first inorganic sealing film 31 (bending portion B side end portion E31) and an end EE33 in the bending portion B side of the second inorganic sealing film 33 (bending portion B side end portion E33) that form the sealing film 35f) is an end that corresponds to a side of an opening end of a CVD mask (end of the TFE-CVD films). Note that the first inorganic sealing film 31, which forms the layer underlying the sealing film 35f (first CVD film), is preferably made of an inorganic material containing silicon oxynitride (SiON) as a primary component. The second inorganic sealing film 33, which forms a layer overlying the sealing film 35f, is preferably made of an inorganic material containing silicon nitride (SiNx where x is a positive number) as a primary component. Note that in the present specification, the “primary component” refers to the component that accounts for more than 50 mass % of the component materials.

Referring to FIG. 7, the touch panel layer 40f includes: a base coat film 41 (hereinafter, may be referred to as a “second base coat film 41”); the plurality of lead wires 43 provided on the second base coat film 41; and an overcoat film 47 provided so as to cover the plurality of lead wires 43. Note that the first lead wires 43a and the second lead wires 43b, described above as the lead wires 43, all have the same structure and therefore will be collectively discussed below.

Referring to FIG. 7, the second base coat film 41 forms a layer underlying the touch panel layer 40. The second base coat film 41 is provided as a layer underlying the lead wires 43. The second base coat film 41 is provided so as to cover the sealing film 35f (specifically, the second inorganic sealing film 33 that forms the sealing film 35f) in the frame area F closer to the display area D than to the bending portion B. Meanwhile, the second base coat film 41 is provided on the second planarization film 27 that forms a layer overlying the TFT layer 20 in the frame area F toward the bending portion B. The second base coat film 41 is made of, for example, either a monolayer, inorganic insulating film of silicon nitride (SiNx where x is a positive number), silicon oxide (SiO₂), or silicon oxynitride (SiON) or a stack of any of these films.

As described above, the lead wires 43 are formed by a stack of the first conductive layer and the second conductive layer. Specifically, the lead wires 43 include the lower lead wires 44 that are formed by the first conductive layer and upper lead wires 46 that are formed by the second conductive layer. The lead wires 43 have a layered structure in which the lower lead wires 44 and the upper lead wires 46 are sequentially stacked.

Referring to FIG. 7, there are provided a plurality of lower lead wires 44 on the second base coat film 41. The bending portion B side ends of the lower lead wires 44 are located in the display area D side with respect to the bending portion B side end portions E31, E33 of the first inorganic sealing film 31 and the second inorganic sealing film 33.

Referring to FIG. 7, the touch panel layer 40f further includes an inter-lead wire insulating film 45 between the lower lead wires 44 and the upper lead wires 46.

Referring to FIG. 7, the inter-lead wire insulating film 45 is provided on the lower lead wires 44 and the second base coat film 41 so as to cover the bending portion B side ends of the lower lead wires 44. The inter-lead wire insulating film 45 is provided to insulate the bending portion B side ends of the lower lead wires 44 from the bending portion B side ends of the upper lead wires 46. Therefore, the periphery of the display area D side end of the inter-lead wire insulating film 45 is provided between the lower lead wires 44 and the upper lead wires 46. Meanwhile, the inter-lead wire insulating film 45 in those parts other than the display area D side end is provided between the second base coat film 41 and the overcoat film 47.

Referring to FIG. 7, there are provided a plurality of upper lead wires 46 on the inter-lead wire insulating film 45 and the lower lead wires 44 so as to cover the display area D side end of the inter-lead wire insulating film 45. The bending portion B side ends of the upper lead wires 46 are located in the display area D side with respect to the bending portion B side end portions E31, E33 of the first inorganic sealing film 31 and the second inorganic sealing film 33.

The overcoat film 47 forms a layer (protective layer) overlying the touch panel layer 40f. Referring to FIG. 7, the overcoat film 47 is provided on the inter-lead wire insulating film 45 and the upper lead wires 46 so as to cover the bending portion B side ends of the second base coat film 41, the inter-lead wire insulating film 45, and the upper lead wires 46. The overcoat film 47 is made of, for example: a monolayer inorganic insulating film of, for example, silicon nitride (SiNx where x is a positive number), silicon oxide (SiO₂), or silicon oxynitride (SiON) or a stack of any of these films; or an organic material such as an acrylic resin, a polyurea resin, a parylene resin, a polyimide resin, or a polyamide resin. In other words, the overcoat film 47 may be made of an inorganic film or an organic film.

As described above, the first contact holes Ha are portions (connecting portions) for connecting the lead wires 43 (specifically, the lower lead wires 44) (the bending portion B side ends thereof) to the bend lines 26 (the display area D side ends thereof). Referring to FIG. 7, the first contact holes Ha are formed in the display area D side of the frame area F with respect to the bending portion B. The first contact holes Ha are provided for each bend line 26 so as to expose at least parts of the display area D side ends of the bend lines 26. Referring to FIGS. 7 and 8, the first contact holes Ha are formed through the second planarization film 27, the sealing film 35f, and the second base coat film 41. Specifically, the first contact holes Ha are formed so as to run through, the second base coat film 41, the first inorganic sealing film 31 and the second inorganic sealing film 33, both in the sealing film 35f, and the second planarization film 27 on the bend lines 26. Note that FIG. 8 does not show the layer underlying the first the planarization film 19 and the layer overlying the second base coat film 41.

As described above, the second contact holes Hb are portions (connecting portions) for connecting the bend lines 26 (terminal section T side ends thereof) to the terminals t of the terminal section T. Specifically, the terminal section T side ends of the bend lines 26 are connected to the lead wires 43 (specifically, the lower lead wires 44) in the touch panel layer 40f provided in the terminal section T side with respect to the bending portion B via the second contact holes Hb. Referring to FIG. 7, the second contact holes Hb are formed in the terminal section T side of the frame area F with respect to the bending portion B. The second contact holes Hb are provided for each bend line 26 so as to expose at least parts of the terminal section T side ends of the bend lines 26. The second contact holes Hb are formed through the second planarization film 27 and the second base coat film 41. Specifically, the second contact holes Hb are formed so as to run through the second base coat film 41 and the second planarization film 27 on the bend lines 26.

Here, in the organic EL display device 50a, the bending portion B side end portion E35 of the sealing film 35f is provided in the terminal section T (the bending portion B) side with respect to the first contact holes Ha. Specifically, referring to FIGS. 7 and 8, the bending portion B side end portion E31 of the first inorganic sealing film 31 and the bending portion B side end portion E33 of the second inorganic sealing film 33, in the sealing film 35f, are both provided in the bending portion B side with respect to the first contact holes Ha. Referring to FIG. 7, both the bending portion B side end portion E31 and the bending portion B side end portion E33 are provided between the first contact holes Ha and the bending portion B. Both the bending portion B side end portion E31 and the bending portion B side end portion E33 do not overlap the lead wires 43 (specifically, the bending portion B side ends thereof) in a plan view, but overlap the bend lines 26 in a plan view. In the organic EL display device 50a structured as described above, the lead wires 43 (the lower lead wires 44 and the upper lead wires 46) straddle neither the bending portion B side end portion E31 nor the bending portion B side end portion E33.

In other words, in the organic EL display device 50a, the film-forming regions of the first inorganic sealing film 31 and the second inorganic sealing film 33 in the sealing film 35f are expanded toward the terminal section T (toward the bending portion B) side. Specifically, referring to FIG. 7, both the first inorganic sealing film 31 and the second inorganic sealing film 33 are formed as far as a region that is in the bending portion B side with respect to the first contact holes Ha and that is between the first contact holes Ha and the bending portion B. The first inorganic sealing film 31 and the second inorganic sealing film 33 are provided so as to overlap the bend lines 26 in a plan view. Therefore, the first contact holes Ha in which the bend lines 26 are connected to the lead wires 43 are formed inside the first inorganic sealing film 31 and the second inorganic sealing film 33. Specifically, referring to FIGS. 7 and 8, the first contact holes Ha are formed so as to run through the first inorganic sealing film 31 and the second inorganic sealing film 33.

Then, in the organic EL display device 50a, referring to FIGS. 7 and 8, no lead wires 43 are provided (present) on the bending portion B side end portion E35 (E31, E33) of the sealing film 35f located in the bending portion B side with respect to the first contact holes Ha. In other words, the lead wires 43 do not straddle the bending portion B side end portion E35 (E31, E33). As a result, the lead wires 43 (the bending portion B side ends thereof) remain covered by the overcoat film 47 even if the bending portion B side end portion (CVD film end) E35 of the sealing film 35f change its nature in a high-temperature, high-humidity environment, thereby causing cracks in the overlying overcoat film 47. In other words, the lead wires 43 are unlikely to be affected by the change of nature of the CVD film end and restrained from corrosion and hence from degradation.

In the organic EL display device 50a structured as above, each subpixel P is structured so as to turn on the first TFT 9a by feeding a gate signal to the first TFT 9a via the gate line 14, thereby writing a voltage corresponding to a source signal to the gate electrode 14b of the second TFT 9b and the capacitor 9c via the source line 18f, and so as also to cause the light-emitting layer 3 in the organic EL layer 23 to emit light for an image display by feeding to the organic EL layer 23 an electric current from the power supply line 18g specified on the basis of the gate voltage of the second TFT 9b. Note that in the organic EL display device 50a, even when the first TFT 9a is turned off, the light-emitting layer 3 continuously emits light until a gate signal is fed in the next frame because the gate voltage of the second TFT 9b is retained by the capacitor 9c.

A description will be given next of a method of manufacturing the organic EL display device 50a in accordance with the present embodiment. A method of manufacturing the organic EL display device 50a involves a TFT layer formation step, an organic EL element layer formation step, a sealing film formation step, and a touch panel layer formation step.

### TFT Layer Formation Step

For instance, the TFT layer 20 is formed by, for example, forming the base coat film 11, the first TFTs 9a, the second TFTs 9b, the capacitors 9c, and the first the planarization film 19 on the surface of the resin substrate 10 provided on a glass substrate by a well-known method. In addition, when, for example, the source electrodes 18a, 18c, the drain electrodes 18b, 18d, and the power supply lines 18g are formed as the third wiring layer, the bend lines 26 are also formed on the first the planarization film 19 in the frame area F toward the bending portion B. Furthermore, the second planarization film 27 is formed of the same material on the bend lines 26 and the first the planarization film 19 similarly to the first the planarization film 19, so as to cover the bend lines 26.

### Organic EL Element Layer Formation Step

The organic EL elements 25 are formed, and the organic EL element layer 30 is formed, by forming the first electrodes 21, the edge cover 22, the organic EL layer 23 (the hole injection layer 1, the hole transport layer 2, the light-emitting layer 3, the electron transport layer 4, and the electron injection layer 5) and the second electrodes 24 on the first the planarization film 19 of the TFT layer 20 formed in the TFT layer formation step (specifically, on the first the planarization film 19 in the display area D) by a well-known method.

### Sealing Film Formation Step

The sealing film formation step involves a first inorganic sealing film formation step, an organic sealing film formation step, and a second inorganic sealing film formation step.

### First Inorganic Sealing Film Formation Step

The first inorganic sealing film 31 is formed by, for example, forming a silicon oxynitride (SiON) film on the surface of the substrate on which the organic EL element layer 30 has been formed, by plasma CVD using a CMM as a vapor deposition mask so as to cover the organic EL elements 25.

### Organic Sealing Film Formation Step

Subsequently, the organic sealing film 32 is formed on the first inorganic sealing film 31 by forming a film of an organic resin material such as an acrylic resin by, for example, inkjet printing.

### Second Inorganic Sealing Film Formation Step

Thereafter, the second inorganic sealing film 33 is formed by, for example, forming a silicon nitride film by plasma CVD using a CMM as a vapor deposition mask so as to cover the organic sealing film 32.

These steps form, in the display area D, the sealing film 35d in which the first inorganic sealing film 31, the organic sealing film 32, and the second inorganic sealing film 33 are sequentially stacked.

Meanwhile, in the frame area F, the sealing film 35f can be formed in which the first inorganic sealing film 31 and the second inorganic sealing film 33 are sequentially stacked, except for the organic sealing film 32. In so doing, the sealing film 35f is not formed in the frame area F toward the bending portion B including the bending portion B to accommodate the bending structure in the frame area F. Specifically, referring to FIGS. 7 and 8, in the first inorganic sealing film formation step, the first inorganic sealing film 31 is formed by patterning the first inorganic sealing film 31 in the frame area F, so as to form the bending portion B side end portion E31 before the bending portion B (in the display area D side with respect to the bending portion B). Subsequently, in the second inorganic sealing film formation step, the second inorganic sealing film 33 is formed by patterning the second inorganic sealing film 33 in the frame area F, so as to form the bending portion B side end portion E33 before the bending portion B. In other words, the film-forming regions of the first inorganic sealing film 31 and the second inorganic sealing film 33 are altered (expanded toward the bending portion B side) so that the bending portion B side end portion E31 and the bending portion B side end portion E33 overlap the bend lines 26 in a plan view (specifically, the display area D side end vicinity thereof).

### Touch Panel Layer Formation Step

The touch panel layer formation step involves a base coat film formation step, a contact hole formation step, a lower lead wire formation step, an inter-lead wire insulating film formation step, an upper lead wire formation step, and an overcoat film formation step.

### Base Coat Film Formation Step

The second base coat film 41 is formed by forming either a monolayer inorganic insulating film of, for example, silicon nitride, silicon oxynitride, or silicon oxide or a stack of any of these films by, for example, plasma CVD, so as to cover the sealing film 35d and the sealing film 35f formed in the sealing film formation step. In addition, the second base coat film 41 is formed on the second planarization film 27 in the terminal section T side of the frame area F with respect to the bending portion B, similarly to the foregoing.

### Contact Hole Formation Step

Referring to FIGS. 7 and 8, the first contact holes Ha are formed in the display area D side with respect to the bending portion B, by patterning the second base coat film 41 and the second inorganic sealing film 33 and the first inorganic sealing film 31 in the sealing film 35f sequentially from above in a suitable manner by, for example, photolithography on the surface of the substrate on which the second base coat film 41 has been formed on the sealing film 35f. In addition, referring to FIG. 7, the second contact holes Hb are formed in the terminal section T side with respect to the bending portion B by patterning the second base coat film 41 in a suitable manner similarly to the foregoing on the surface of the substrate on which the second base coat film 41 has been formed on the second planarization film 27. In so doing, the first contact holes Ha and the second contact holes Hb are formed so as to reach the display area D side ends and the terminal section T side ends of the bend lines 26 respectively, so as to expose these top faces. In addition, the first contact holes Ha are formed in the display area D side of the bending portion B side end portions E31, E33 of the first inorganic sealing film 31 and the second inorganic sealing film 33. Hence, the bending portion B side end portion E31 and the bending portion B side end portion E33 are formed in the bending portion B side with respect to the first contact holes Ha.

### Lower Lead Wire Formation Step

The plurality of lower lead wires 44 are formed by forming, by, for example, sputtering, either a metal monolayer film (molybdenum film to a thickness of approximately 200 nm) or a stacked metal layer film in which a titanium film (approximately 50 nm in thickness), an aluminum film (approximately 600 nm in thickness), and a titanium film (approximately 50 nm in thickness) are sequentially formed on the surface of the substrate on which the first contact holes Ha and the second contact holes Hb have been formed and thereafter patterning this metal monolayer film or stacked metal layer film by photolithography.

### Inter-Lead Wire Insulating Film Formation Step

The inter-lead wire insulating film 45 is formed by forming either a monolayer inorganic insulating film of, for example, silicon nitride, silicon oxynitride, or silicon oxide or a stack of any of these films by, for example, plasma CVD on the surface of the substrate on which the lower lead wires 44 have been formed, so as to cover the bending portion B side ends of the lower lead wires 44.

### Upper Lead Wire Formation Step

The plurality of upper lead wires 46 are formed by forming, by, for example, sputtering a metal monolayer film (molybdenum film to a thickness of approximately 200 nm) or a stacked metal layer film in which a titanium film (approximately 50 nm in thickness), an aluminum film (approximately 600 nm in thickness), and a titanium film (approximately 50 nm in thickness) are sequentially formed on the surface of the substrate on which the lower lead wires 44 and the inter-lead wire insulating film 45 have been formed and thereafter patterning this metal monolayer film or stacked metal layer film.

### Overcoat Film Formation Step

The overcoat film 47 is formed by forming either a monolayer inorganic insulating film of, for example, silicon nitride, silicon oxynitride, or silicon oxide by, for example, plasma CVD or a stack of any of these films or a film of an organic resin material such as an acrylic resin by inkjet printing on the surface of the substrate on which the upper lead wires 46 have been formed, so as to cover the second base coat film 41, the inter-lead wire insulating film 45, and the upper lead wires 46.

Finally, after attaching a protection sheet (not shown) to the surface of the substrate, the glass substrate is detached from the bottom face of the resin substrate 10 by irradiating the glass substrate side of the resin substrate 10 with a laser beam, and a protection sheet (not shown) is attached to the bottom face of the resin substrate 10 from which the glass substrate has been detached.

The organic EL display device 50a in accordance with the present embodiment is manufactured as described in the foregoing.

### Effects

As described above, the organic EL display device 50a and the method of manufacturing the organic EL display device 50a in accordance with the present embodiment can deliver the following effects.

In the organic EL display device 50a including an OCT mounted thereto (the touch panel layer 40 provided on the sealing film 35) and a bending structure (bending portion B), the first inorganic sealing film 31 and the second inorganic sealing film 33, which form the sealing film 35f, are not formed in the frame area F toward the bending portion B including the bending portion B. In other words, the sealing film 35f and the touch panel layer 40 overlying the sealing film 35f are not provided in the bending portion B. Therefore, the bend lines 26 drawn out from the touch panel layer 40 to connect to the lead wires 43 are provided in the bending portion B. The bend lines 26 and the lead wires 43 are electrically connected together via the first contact holes Ha. In the organic EL display device 50a structured as described here, the bending portion B side end portion E31 of the first inorganic sealing film 31 and the bending portion B side end portion E33 of the second inorganic sealing film 33 are provided in the bending portion B side with respect to the first contact holes Ha. In other words, the lead wires 43 extended all the way to the first contact holes Ha straddle neither the bending portion B side end portion E31 nor the bending portion B side end portion E33. Therefore, even if the film quality has changed its nature in the bending portion B side end portions E31, E33 (in particular, in the bending portion B side end portion E31), thereby causing cracks in the overcoat film 47 forming a layer overlying the lead wires 43, those portions in which nature has changed will unlikely affect connection between the lead wires 43 and the bend lines 26 because such portions occur closer to the bending portion B side than to the first contact holes Ha (i.e., portions where the lead wires 43 and the bend lines 26 are connected together). Therefore, the organic EL display device 50a including an OCT mounted thereto and also a bending structure can restrain corrosion of the lead wires 43.

The method of manufacturing the organic EL display device 50a only requires, in comparison with known steps, altering (expanding) the film-forming region of the sealing film 35f (both the first inorganic sealing film 31 and the second inorganic sealing film 33 in the present embodiment) in the frame area F toward the bending portion B and performing an additional step of patterning the sealing film 35f (step of forming the first contact holes Ha through the sealing film 35f). In other words, the organic EL display device 50a having this structure can be readily manufactured.

### Second Embodiment

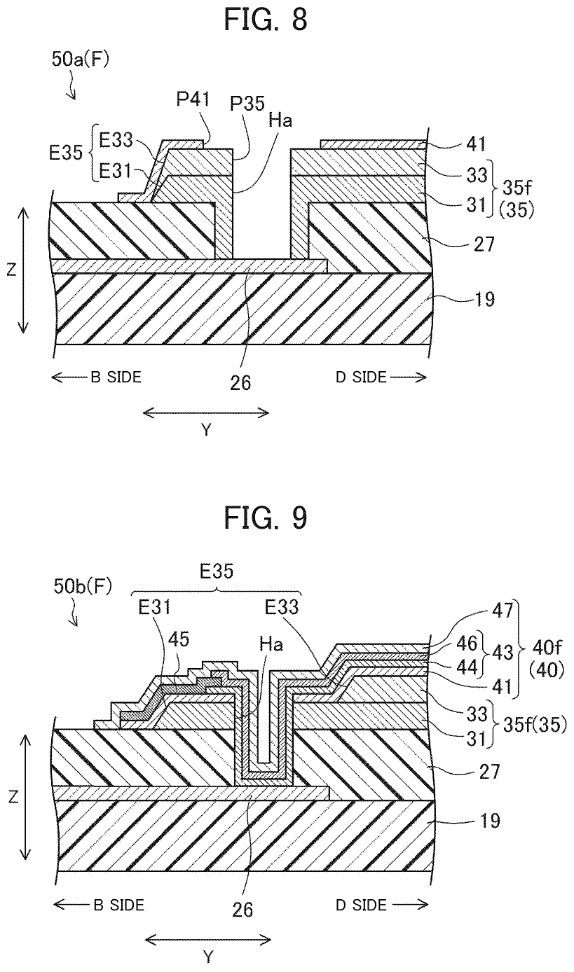

A description is now given of a second embodiment of the disclosure. FIG. 9 illustrates the second embodiment of the display device in accordance with the disclosure. FIG. 9 is a cross-sectional view of a frame area F in a bending portion B side of an organic EL display device 50b in accordance with the present embodiment and corresponds to FIG. 7. Note that FIG. 9 omits the layer underlying the first the planarization film 19.

The organic EL display device 50b has the same overall structure as the case of the first embodiment described above except for the structure of the sealing film 35f, and the detailed description thereof is omitted here. In addition, members that are identical or equivalent to those in the first embodiment are denoted by the same reference numerals, and the description thereof is omitted.

While the film-forming regions of both the first inorganic sealing film 31 and the second inorganic sealing film 33 in the sealing film 35f are altered (expanded) in the organic EL display device 50a in accordance with the first embodiment described above as shown in FIGS. 7 and 8, only the film-forming region of the lower, first inorganic sealing film 31 which is likely to change its nature is altered in the organic EL display device 50b in accordance with the present embodiment as shown in FIG. 9.

Specifically, referring to FIG. 9, the bending portion B end E31 of the first inorganic sealing film 31 is provided in the bending portion B side with respect to the first contact holes Ha. Meanwhile, the bending portion B end E33 of the second inorganic sealing film 33 is provided in the display area D side with respect to the first contact holes Ha. In other words, the first contact holes Ha are formed in the first inorganic sealing film 31 so as to run through the first inorganic sealing film 31, but not in the second inorganic sealing film 33.

The organic EL display device 50b in accordance with the present embodiment can be manufactured by altering a pattern shape in forming the first inorganic sealing film 31 in the first inorganic sealing film formation step in the sealing film formation step in the method of manufacturing the organic EL display device 50a in accordance with the first embodiment described above.

### Effects

The organic EL display device 50b and the method of manufacturing the organic EL display device 50b in accordance with the present embodiment can deliver the same effects as the foregoing. Specifically, the organic EL display device 50b is structured so that the lead wires 43 do not straddle the bending portion B end E31 of the first inorganic sealing film 31 (first CVD film) which, in the sealing film 35f, is likely to change its nature in a high-temperature, high-humidity environment. Therefore, even if the film quality has changed its nature in the bending portion B end E31, thereby causing cracks in the overcoat film 47 forming a layer overlying the lead wires 43, corrosion of the lead wires 43 can be restrained.

In addition, in the organic EL display device 50b, the first contact holes Ha are provided only in the first inorganic sealing film 31 in the sealing film 35f. Hence, the etching film thickness in patterning the first inorganic sealing film 31 is reduced, and for this reason, attempts to prevent breaks in the first contact holes Ha become possible. In addition, the hole diameter of the first contact holes Ha is reduced, and for this reason, attempts to reduce the frame in size become possible.

In addition, according to the method of manufacturing the organic EL display device 50b, the etching film thickness in patterning the first inorganic sealing film 31 is reduced, and for this reason, workload in the contact hole formation step can be reduced. Specifically, attempts to reduce etching time become possible, and additionally, the control of the process is facilitated.

### Third Embodiment

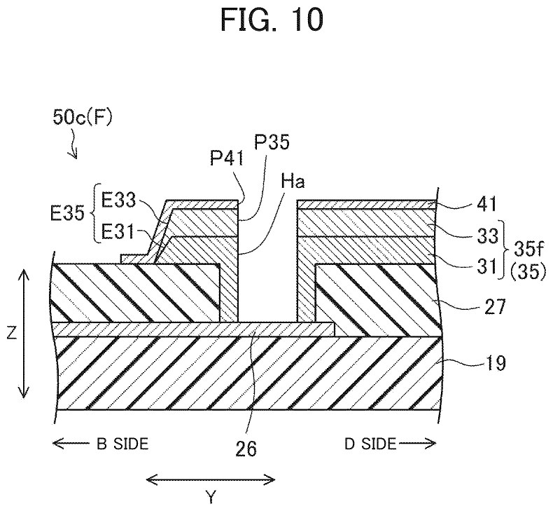

A description is now given of a third embodiment of the disclosure. FIG. 10 illustrates the third embodiment of the display device in accordance with the disclosure. FIG. 10 is an enlarged cross-sectional view of a frame area F in the bending portion B side of an organic EL display device 50c in accordance with the present embodiment and corresponds to FIG. 8. Note that FIG. 10 omits the layer underlying the first the planarization film 19 and the layer overlying the second base coat film 41.

The organic EL display device 50c has the same overall structure as the case of the first embodiment described above except for the structure of the sealing film 35f, and the detailed description thereof is omitted here. In addition, members that are identical or equivalent to those in the first embodiment are denoted by the same reference numerals, and the description thereof is omitted.

While a hole diameter P41 of patterned openings in the second base coat film 41 differs from a hole diameter P35 of patterned openings in the sealing film 35f in forming the first contact holes Ha in the organic EL display device 50a in accordance with the first embodiment described above as shown in FIG. 8, the hole diameter P41 is equal to the hole diameter P35 in the organic EL display device 50c in accordance with the present embodiment as shown in FIG. 10. Note that this structure in accordance with the present embodiment is applicable also to the organic EL display device 50b in accordance with the second embodiment described above. In this case, the hole diameter P41 is equal to the hole diameter (not shown) of patterned openings in the lower, first inorganic sealing film 31 which is the first CVD film in the sealing film 35f.

The organic EL display device 50c in accordance with the present embodiment can be manufactured by simultaneously performing, in the base coat film formation step, the contact hole formation step which is a part of the touch panel layer formation step in the method of manufacturing the organic EL display device 50a in accordance with the first embodiment described above. Specifically, the first contact holes Ha and the second contact holes Hb are formed by, in the base coat film formation step, forming a monolayer inorganic insulating film or a stack of such films and thereafter patterning the sealing film 35f (the second inorganic sealing film 33 and the first inorganic sealing film 31 when applied to the organic EL display device 50a and only the first inorganic sealing film 31 when applied to the organic EL display device 50b) simultaneously with the second base coat film 41. This collective patterning of the second base coat film 41 and the sealing film 35f changes the structure in alignment margin relationship, thereby reducing discrepancy in alignment.

### Variation Example of Third Embodiment

In addition, in the organic EL display device 50c in accordance with the present embodiment, the patterning of the frame area F toward the bending portion B (specifically, for example, the first inorganic sealing film 31, the second inorganic sealing film 33, the first contact holes Ha, and the second contact holes Hb) may be simultaneously performed in the contact hole formation step. Specifically, first, the first inorganic sealing film 31 and the second inorganic sealing film 33 are not patterned using a CVD mask, but formed across the entire surface of the substrate, in the first inorganic sealing film formation step and the second inorganic sealing film formation step. Subsequently, the second base coat film 41 is formed in a prescribed region in the base coat film formation step. Thereafter, in the contact hole formation step, for example, the first inorganic sealing film 31, the second inorganic sealing film 33, and the second base coat film 41 in the frame area F toward the bending portion B including the bending portion B are collectively patterned by, for example, photolithography. Note that the variation example of the present embodiment is applicable also to the organic EL display device 50b in accordance with the second embodiment described above.

### Effects

The organic EL display device 50c and the method of manufacturing the organic EL display device 50c in accordance with the present embodiment and the variation example thereof can deliver the same effects as the foregoing and additionally allow for attempts to reduce the frame in size and the number of manufacturing steps involved. In addition, the variation example of the organic EL display device 50c and the method of manufacturing the variation example are additionally advantageous in eliminating the need for costly TFE-CVD masks and hence in reducing cost.

### Other Embodiments

The foregoing embodiments have discussed examples where the organic EL layer has a 5-layer structure that includes a hole injection layer, a hole transport layer, a light-emitting layer, an electron transport layer, and an electron injection layer. Alternatively, the organic EL layer may have, for example, a 3-layer structure that includes a hole injection and transport layer, a light-emitting layer, and an electron transport and injection layer.

The foregoing embodiments have discussed examples where the organic EL display device includes a first electrode as an anode and a second electrode as a cathode. The disclosure is equally applicable to organic EL display devices in which the layered structure of the organic EL layer is reversed, to include a first electrode as a cathode and a second electrode as an anode.

The foregoing embodiments have discussed examples where the organic EL display device includes an electrode of a TFT connected to the first electrode as a drain electrode. The disclosure is equally applicable to organic EL display devices in which the electrode of a TFT connected to the first electrode is referred to as the source electrode.

The foregoing embodiments have discussed organic EL display devices as an example of the display device. The disclosure is equally applicable to display devices including liquid crystal display devices that operate by an active matrix driving scheme.

The foregoing embodiments have discussed organic EL display devices as an example of the display device. The disclosure is equally applicable to display devices including a plurality of current-driven light-emitting elements, for example, applicable to display devices including QLEDs (quantum-dot light-emitting diodes) which are light-emitting elements using a quantum-dot-containing layer.

### Industrial Applicability

The disclosure is useful in flexible display devices as described above.

1. A display device comprising:
a base substrate;
a thin film transistor layer on the base substrate;
a light-emitting element layer on the thin film transistor layer, the light-emitting element layer constituting at least a part of a display area;
a sealing film provided so as to cover the light-emitting element layer; and
a touch panel layer on the sealing film, the touch panel layer constituting at least a part of a touch panel, the display device further comprising:
a frame area around the display area;
a terminal section in the frame area; and
a bending portion between the terminal section and the display area, the bending portion being configured so as to extend in a single direction, wherein
in the sealing film in the frame area, a bending portion side end portion is provided between the bending portion and the display area,
on the sealing film, a plurality of lead wires drawn out from the touch panel are provided, the plurality of lead wires constituting at least a part of the touch panel layer,
the plurality of lead wires do not straddle the bending portion side end portion of the sealing film,
in the frame area toward the bending portion, there are provided:
a plurality of bend lines on the thin film transistor layer, each of the plurality of bend lines having an end electrically connected to the terminal section; and
a plurality of contact holes provided so as to expose at least a part of another end of each of the plurality of bend lines,
the plurality of bend lines and the plurality of lead wires are electrically connected respectively via the plurality of contact holes,
the bending portion side end portion of the sealing film is provided in the bending portion side of the plurality of contact holes,
the sealing film in the frame area is structured to have a layered structure in which a first inorganic sealing film and a second inorganic sealing film are sequentially stacked,
the plurality of lead wires do not straddle a bending portion side end portion of the first inorganic sealing film,
the bending portion side end portion of the first inorganic sealing film is provided in the bending portion side of the plurality of contact holes, and
the bending portion side end portion of the second inorganic sealing film is provided in the display area side of the plurality of contact holes.

2. The display device according to claim 1, wherein the plurality of lead wires do not overlap the bending portion side end portion of the sealing film in a plan view.

3. (canceled)

4. The display device according to claim wherein the bending portion side end portion of the sealing film is provided between the plurality of contact holes and the bending portion.

5. The display device according to claim 1, wherein the bending portion side end portion of the sealing film overlaps the plurality of bend lines in a plan view.

6. The display device according to claim 1, wherein the plurality of contact holes are provided so as to run through the sealing film.

7-11. (canceled)

12. The display device according to claim further comprising a planarization film provided so as to cover the plurality of bend lines, wherein the first inorganic sealing film is provided on the planarization film.

13. The display device according to claim 1, wherein the touch panel layer in the frame area includes, on the first inorganic sealing film and the second inorganic sealing film:
a base coat film as a layer underlying the plurality of lead wires; and
an overcoat film provided so as to cover the plurality of lead wires.

14. The display device according to claim 1, wherein each of the plurality of lead wires is structured to have a layered structure in which a lower lead wire and an upper lead wire are sequentially stacked.

15. The display device according to claim 14, wherein the touch panel layer in the frame area toward the bending portion includes an inter-lead wire insulating film interposed between the lower lead wires and the upper lead wires.

16. The display device according to claim 1, wherein the first inorganic sealing film contains an inorganic material containing a silicon oxynitride film as a primary component.

17. The display device according to claim 1, wherein the second inorganic sealing film contains an inorganic material containing a silicon nitride film as a primary component.

18. A method of manufacturing a display device comprising:
a base substrate;
a thin film transistor layer on the base substrate;
a light-emitting element layer on the thin film transistor layer, the light-emitting element layer constituting at least a part of a display area;
a sealing film provided so as to cover the light-emitting element layer; and
a touch panel layer on the sealing film, the touch panel layer constituting at least a part of a touch panel, the display device further comprising:
a frame area around the display area;
a terminal section in the frame area; and
a bending portion between the terminal section and the display area, the bending portion being configured so as to extend in a single direction,
the method comprising:
a thin film transistor layer formation step of forming the thin film transistor layer on the base substrate;
a light-emitting element layer formation step of forming the light-emitting element layer on the thin film transistor layer;
a sealing film formation step of forming the sealing film so as to cover the light-emitting element layer; and
a touch panel layer formation step of forming the touch panel layer on the sealing film, wherein
the touch panel layer formation step comprises a lead wire formation step of forming a plurality of lead wires on the sealing film, the plurality of lead wires being drawn out from the touch panel and constituting at least a part of the touch panel layer,
when in the sealing film formation step, the sealing film in the frame area is patterned to form a bending portion side end portion between the bending portion and the display area, a film-forming region of the sealing film is expanded toward the bending portion side so that the plurality of lead wires do not straddle the bending portion side end portion of the sealing film,
when in the sealing film formation step, a first inorganic sealing film and a second inorganic sealing film are sequentially formed and patterned to form each bending portion side end portion, a film-forming region of the first inorganic sealing film is expanded toward the bending portion side so that the plurality of lead wires do not straddle a bending portion side end portion of the first inorganic sealing film,
in the thin film transistor layer formation step, a plurality of bend lines are formed on the thin film transistor layer in the frame area toward the terminal section, each of the plurality of bend lines having an end electrically connected to the terminal section,
the touch panel layer formation step comprises, before the lead wire formation step, a contact hole formation step of exposing at least a part of another end of each of the plurality of bend lines and forming a plurality of contact holes configured to electrically connect the plurality of bend lines and the plurality of lead wires respectively,
in the sealing film formation step, the bending portion side end portion of the first inorganic sealing film is provided in the bending portion side of the plurality of contact holes, and
in the sealing film formation step, the bending portion side end portion of the second inorganic sealing film is provided in the display area side of the plurality of contact holes.

19-23. (canceled)

24. The method according to claim 18, wherein
the touch panel layer formation step comprises, before the contact hole formation step, a base coat film formation step of forming a base coat film as a layer underlying the plurality of lead wires on the first inorganic sealing film and the second inorganic sealing film, and
in the base coat film formation step, the contact hole formation step is simultaneously performed by collectively patterning the base coat film, the first inorganic sealing film, and the second inorganic sealing film to form the plurality of contact holes.

25. The method according to claim 18, wherein
the touch panel layer formation step comprises, before the contact hole formation step, a base coat film formation step of forming a base coat film as a layer underlying the plurality of lead wires on the first inorganic sealing film and the second inorganic sealing film,
in the sealing film formation step, the first inorganic sealing film and the second inorganic sealing film are sequentially formed across the entire frame area, and
in the contact hole formation step, patterning in the sealing film formation step and patterning the base coat film formation step are simultaneously performed by collectively patterning the base coat film, the first inorganic sealing film, and the second inorganic sealing film by photolithography to form the plurality of contact holes.
